(19) United States
(12) Patent Application Publication
(10) Pub. No.: US 2025/0290201 A1
(43) Pub. Date: Sep. 18, 2025

(54) FILM FORMATION APPARATUS AND FILM FORMATION METHOD

(71) Applicant: Tokyo Electron Limited, Tokyo (JP)

(72) Inventors: Taichi MONDEN, Nirasaki City (JP); Yasushi FUJII, Nirasaki City (JP); Hiroo KAWASAKI, Nirasaki City (JP)

(21) Appl. No.: 19/226,399

(22) Filed: Jun. 3, 2025

Related U.S. Application Data
(63) Continuation of application No. PCT/JP2023/043694, filed on Dec. 6, 2023.

(30) Foreign Application Priority Data
Dec. 15, 2022 (JP) 2022-200209

(51) Int. Cl. C23C 16/455; C23C 16/44

(52) U.S. Cl. CPC C23C 16/45544; C23C 16/4409; C23C 16/45565

(57) ABSTRACT

A film formation apparatus includes: a processing container configured to store a substrate, an interior of the processing container being under a vacuum atmosphere; a film formation gas supply including a shower head configured to supply a film formation gas and an upper member configured to form a diffusion space inside the processing container; a first sealing member surrounding the diffusion space and in close contact with the shower head and the upper member, a second sealing member surrounding the first sealing member and in close contact with the shower head and the upper member; and a gas discharge path. An upstream end of the gas discharge path is opened in a gap formed by the first sealing member, the second sealing member, the shower head, and the upper member. A downstream end of the gas discharge path is opened in the processing container.

### CROSS-REFERENCE TO RELATED APPLICATION

The application is a Bypass Continuation Application of PCT International Application No. PCT/JP2023/043694, filed on Dec. 6, 2023 and designating the United States, the international application being based upon and claiming the benefit of priority from Japanese Patent Application No. 2022-200209, filed on Dec. 15, 2022, the entire contents of which are incorporated herein by reference.

### TECHNICAL FIELD

The present disclosure relates to a film formation apparatus and a film formation method.

### BACKGROUND

In manufacturing a semiconductor device, an apparatus for forming a film on a semiconductor wafer (hereinafter, referred to as a “wafer”), which serves as a substrate, is disclosed in Patent Document 1, including a configuration for supplying a raw material gas for film formation to the wafer arranged inside a processing container through a discharge port of a shower head. The shower head is provided at a lower portion of a diffusion chamber of the raw material gas that is provided at an upper portion of the processing container.

### PRIOR ART DOCUMENTS

### Patent Documents

Patent Document 1: Japanese Patent Laid-Open Publication No. 2020-132942

### SUMMARY

According to one embodiment of the present disclosure, a film formation apparatus includes: a processing container configured to store a substrate, an interior of the processing container being under a vacuum atmosphere; a film formation gas supply, which includes a shower head provided with a plurality of discharge holes configured to supply a film formation gas for forming a film on the substrate and an upper member configured to form a diffusion space of the film formation gas communicating with the plurality of discharge holes and provided above the shower head inside the processing container; an annular first sealing member surrounding the diffusion space in a plan view and in close contact with the shower head and the upper member, an annular second sealing member surrounding the first sealing member in the plan view and in close contact with the shower head and the upper member; and a gas discharge path formed in the film formation gas supply, wherein an upstream end of the gas discharge path is opened in a gap formed by the first sealing member, the second sealing member, the shower head, and the upper member, and wherein a downstream end of the gas discharge path is opened in the processing container.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal cross-sectional side view illustrating an embodiment of a film formation apparatus including a film formation gas supply of the present disclosure.

FIG. 2 is a longitudinal cross-sectional side view illustrating a first example of a conventional film formation gas supply.

FIG. 3 is a longitudinal cross-sectional side view illustrating a second example of the conventional film formation gas supply.

FIG. 4A is a longitudinal cross-sectional side view illustrating an embodiment of the film formation gas supply of the present disclosure.

FIG. 4B is an enlarged longitudinal cross-sectional side view illustrating a part of the film formation gas supply.

FIG. 5 is a plan view illustrating a part of the film formation gas supply.

FIG. 6A is a longitudinal cross-sectional side view illustrating a concave portion and a connection path forming member provided in the film formation gas supply.

FIG. 6B is a perspective view illustrating an example of the connection path forming member.

FIG. 7A is a longitudinal cross-sectional side view illustrating an operation of the film formation gas supply.

FIG. 7B is a longitudinal cross-sectional side view illustrating the operation of the film formation gas supply.

FIG. 8A is a longitudinal cross-sectional side view illustrating the operation of the film formation gas supply.

FIG. 8B is a longitudinal cross-sectional side view illustrating the operation of the film formation gas supply.

FIG. 9 is a longitudinal cross-sectional side view illustrating another example of the film formation gas supply of the present disclosure.

FIG. 10 is a schematic plan view of a shower head.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Overview and Conventional Configuration of Film Formation Apparatus

The present disclosure provides a gas discharge path in a film formation gas supply that supplies a film formation gas from the film formation gas supply to a processing container, an interior of which is under a vacuum atmosphere, for forming a film on a wafer, which is a substrate stored in the processing container.

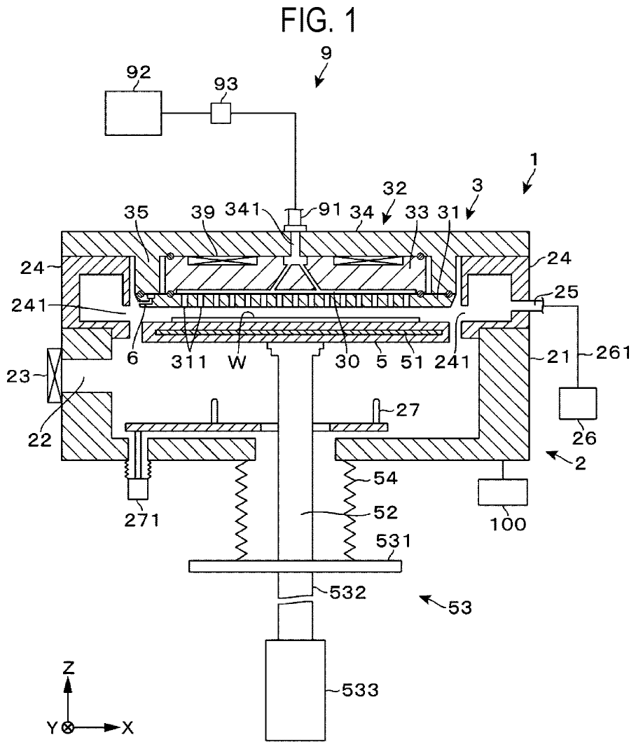

Before describing the film formation gas supply of the present disclosure, a configuration of a conventional film formation gas supply will now be described with reference to FIGS. 1 to 3. FIG. 1 illustrates a configuration example of a film formation apparatus 1 including a film formation gas supply 3 of the present disclosure. However, since a conventional film formation gas supply 3A or 3B is also provided in the film formation apparatus 1 in place of the film formation gas supply 3, reference is made to FIG. 1. As illustrated in FIG. 1, in the film formation apparatus 1, the film formation gas supplies 3, 3A, and 3B are provided on an upper portion of a processing container 2.

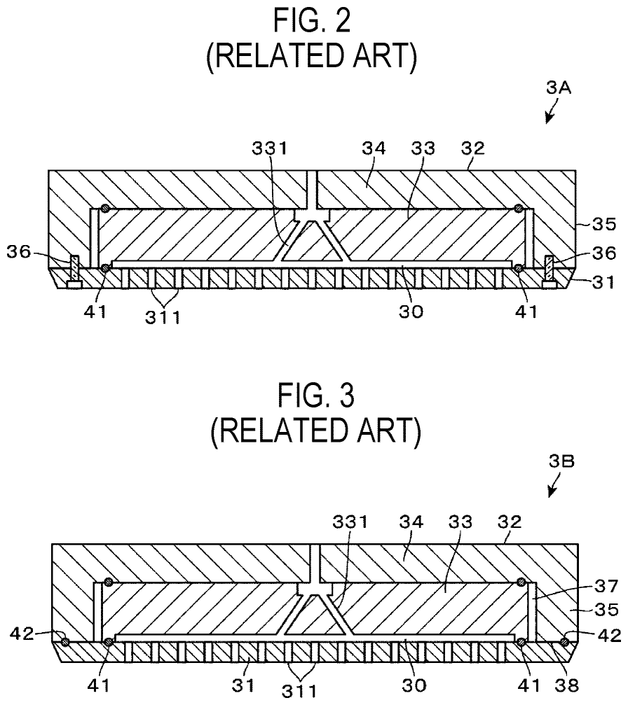

FIG. 2 illustrates a first example of the conventional film formation gas supply 3A. The film formation gas supply 3A includes a shower head 31 facing a wafer W and an upper member 32 provided above the shower head 31. The shower head 31 and the upper member 32 are made of metal. The shower head 31 is provided with a plurality of discharge holes 311, and the upper member 32 is configured to form, between the upper member 32 and the shower head 31, a diffusion space 30 of a film formation gas that communicates with the discharge holes 311.

For example, the upper member 32 includes a flow path forming member 33, which forms the diffusion space 30 and is provided with a gas flow path 331 of the film formation gas, and a ceiling plate member 34, which is provided above the flow path forming member 33 and functions as a ceiling plate of the processing container 2. The ceiling plate member 34 includes a protrusion 35 that protrudes downward on an outer side of the flow path forming member 33. An outer peripheral portion of an upper surface of the shower head 31 is arranged to be connected to a lower surface of the protrusion 35, and the shower head 31 and the protrusion 35 are joined using screws 36 at multiple locations in a circumferential direction. As a result, the shower head 31 is supported by the upper member 32. A joint portion between the shower head 31 and the upper member 32 is located inside the processing container 2. In addition, an annular first sealing member 41 is provided so as to surround the diffusion space 30 in a plan view and to be in close contact with the shower head 31 and the upper member 32 (the flow path forming member 33). That is, the first sealing member 41 is provided between an outer side of the film formation gas supply 3A and the diffusion space 30 within the processing container 2 so as to prevent gas from flowing through the joint portion.

In this film formation gas supply 3A, although the shower head 31 and the upper member 32 (the protrusion 35) are joined using the screws 36, a minute gap is formed in the joint portion. Therefore, during a film formation process, there is a risk that the film formation gas supplied into the processing container 2 may return to the joint portion and form a film at the relevant area, thereby causing damage to the joint portion. Since the joint portion is formed by joining metal members together using the screws 36, minute physical scratches are formed due to torque applied during screw fastening. However, due to film formation in the joint portion, unintended stress may be applied to the area in which the scratches are formed, thereby potentially causing damage to that area. As a result, as time passes, a joint state between the shower head 31 and the upper member 32 may deteriorate, thereby potentially causing particle generation or temperature variations in the shower head 31 (further, variations in processing temperatures between the wafers W) caused by changes in thermal conduction at the joint portion.

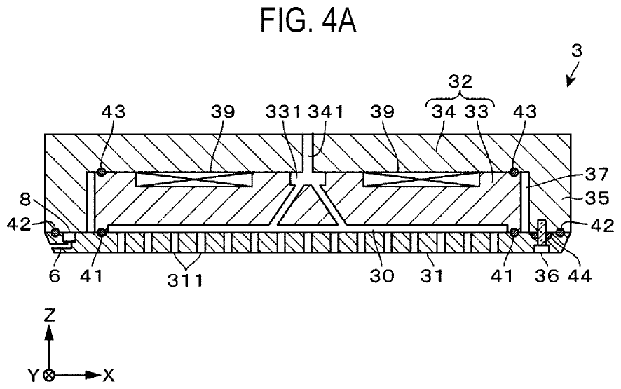

Therefore, as illustrated in FIG. 3, the film formation gas supply 3B, which is a second example of the conventional configuration, includes an annular second sealing member 42 provided outside the first sealing member 41 so as to be in close contact with the shower head 31 and the upper member 32. More specifically, the second sealing member 42 is provided between the protrusion 35, which constitutes a peripheral portion of the upper member 32, and a peripheral portion of the shower head 31. This second sealing member 42 suppresses the film formation gas from returning to the joint portion between the shower head 31 and the upper member 32 inside the second sealing member 42, thereby resolving issues in the film formation gas supply 3A.

However, during manufacture of the film formation apparatus 1 or after maintenance, the film formation gas supply 3B is formed by combining dissembled members in an atmospheric environment. After assembly of the film formation gas supply 3B, atmospheric air remains in a gap 37 between the upper member 32 and the ceiling plate member 34 and in a gap 38 between the first sealing member 41 and the second sealing member 42 in the joint portion between the shower head 31 and the upper member 32. Moreover, the gaps 37 and 38 communicate with each other, and a part of the gap 38 in a radial direction can be considered to extend upward, thereby forming the gap 37.

In this way, the film formation gas supply 3B in which atmospheric air remains is installed in the processing container 2, and the interior of the processing container 2 is under a vacuum atmosphere in order to process the wafer W. However, since the gaps 37 and 38 remain sealed against the outside of the film formation gas supply 3B by the second sealing member 42, it is difficult to discharge the atmospheric air from the gaps 37 and 38. Consequently, even after the film formation process is started, the atmospheric air remains in the gaps 37 and 38, and there is a risk that, although small in quantity, the atmospheric air may leak through the second sealing member 42 during the film formation process and be discharged into the processing container 2. In this case, there is a concern that reaction products (by-products) generated between the atmospheric air and the film formation gas may be mixed into the film on the wafer W, thereby causing issues.

### Configuration of Film Formation Apparatus 1

Based on the above considerations, the film formation gas supply 3 of the present disclosure is provided with a gas discharge path 6 to resolve the issues present in the conventional film formation gas supplies 3A and 3B. An embodiment of the film formation apparatus 1 including this film formation gas supply 3 will now be described with reference to FIGS. 1 and 4A to 6B. For components of the film formation gas supply 3 that are the same as those described in the film formation gas supplies 3A and 3B, the same reference numerals as used in the description of the film formation gas supplies 3A and 3B are used and a further detailed description is given.

The film formation apparatus 1 includes the processing container 2 that stores the wafer W, with an interior of the processing container 2 being under a vacuum atmosphere. The processing container 2 has, for example, a substantially circular planar shape. On a lateral side of the processing container 2, a loading/unloading port 22 for delivering the wafer W between a vacuum transfer chamber, which is an outside of the processing container 2 and not illustrated, and the processing container 2 is provided to be capable of opening and closing by a gate valve 23. Hereinafter, in FIG. 1, a lateral direction is referred to as an X direction, a direction perpendicular to the paper plane is referred to as a Y direction, and a vertical direction is referred to as a Z direction.

Above the loading/unloading port 22, an exhaust duct 24 having a rectangular shape in a longitudinal cross section is provided to be stacked on a side wall 21 which constitutes a main body of the processing container 2. The exhaust duct 24 is provided with a slit-shaped opening 241 formed on an inner peripheral surface of the exhaust duct 24 in a circumferential direction and an exhaust port 25 formed on an outer wall surface of the exhaust duct 24. An exhaust mechanism 26, which includes a vacuum pump or a pressure regulating valve, is connected to the exhaust port 25 via an exhaust path 261, and the interior of the processing container 2 is set to a vacuum atmosphere.

A stage 5 on which the wafer W is placed is arranged at an inner position of the exhaust duct 24 within the processing container 2, and a heater 51 for heating the wafer W is embedded in the stage 5.

A lifting shaft 52 that penetrates a bottom surface of the processing container 2 and extends in the vertical direction is provided at a center of a lower surface of the stage 5, and a lower end of the lifting shaft 52 is connected to a lifting mechanism 53 outside the processing container 2. The lifting mechanism 53 includes a lifting plate 531 to which the lower end of the lifting shaft 52 is connected, a cylinder rod 532, and a motor 533. A space between the bottom surface of the processing container 2 and the lifting plate 531 is connected by a bellows 54.

With this configuration, the stage 5 is configured to be airtightly movable up and down by the lifting mechanism 53 between a processing position (position illustrated in FIG. 1) in which film formation is performed on the wafer W and a delivery position which is located below the processing position and in which the wafer W is delivered via the loading/unloading port 22.

A plurality of support pins 27 for supporting and lifting the wafer W from below during delivery of the wafer W is provided below the stage 5 so as to be raised and lowered by a lifting mechanism 271.

### Film Formation Gas Supply 3

A ceiling portion of the processing container 2 is configured as the film formation gas supply 3. This film formation gas supply 3 includes the shower head 31 and the upper member 32, as previously described. The shower head 31, which is a horizontal plate-shaped member, is arranged to face the wafer W placed on the stage 5 and is configured, for example, in a circular shape in a plan view, with a diameter larger than a diameter of the wafer W. The plurality of discharge holes 311 for supplying the film formation gas to the wafer W placed on the stage 5 is distributed in a region of the shower head 31 facing a placement region of the wafer W on the stage 5 and is provided in a thickness direction of the shower head 31.

The upper member 32 is configured to form the diffusion space 30 of the film formation gas communicating with the discharge holes 311 between the upper member 32 and the shower head 31. In this example, the diffusion space 30 is a circular flat space in a plan view. As previously explained, the upper member 32 includes the flow path forming member 33 and the ceiling plate member 34. The ceiling plate member 34 is installed to be connected to, for example, an upper surface of the flow path forming member 33 and an upper surface of the exhaust duct 24 and includes the annular protrusion 35 protruding downward between the flow path forming member 33 and the exhaust duct 24. In other words, the flow path forming member 33 is surrounded by the protrusion 35. The flow path forming member 33 is a circular block, and a concave portion is formed on a lower surface of the flow path forming member 33. The concave portion forms the diffusion space 30.

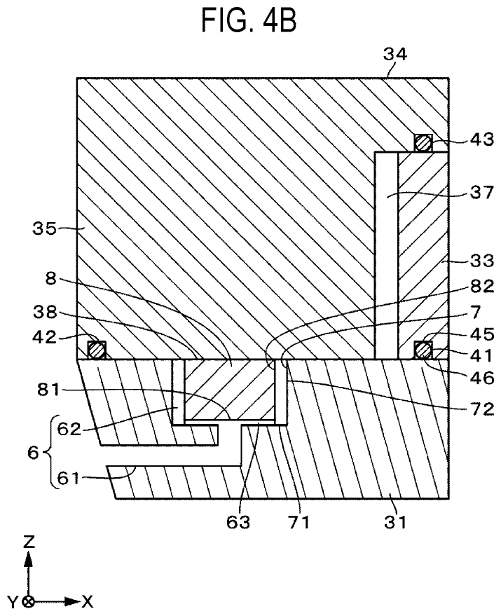

An outer periphery portion of an upper surface of the shower head 31 is provided to be in contact with a lower surface of the protrusion 35 of the upper member 32. As illustrated in FIG. 4A, the shower head 31 and the protrusion 35 are joined using the screw 36. Although FIG. 4A illustrates only one screw 36, a plurality of screws 36 is provided at intervals in a circumferential direction of the shower head 31 and is screwed at multiple positions. In addition, the gap 37 is formed between an outer peripheral surface of the flow path forming member 33 and an inner peripheral surface of the protrusion 35.

The annular first sealing member 41 is provided between the shower head 31 and the upper member 32 so as to surround the diffusion space 30 in a plan view and to be in close contact with the shower head 31 and the flow path forming member 33 of the upper member 32, as illustrated in FIG. 4A. In addition, the annular second sealing member 42 is provided so as to surround the first sealing members 41 in a plan view and to be in close contact with the shower head 31 and the protrusion 35 of the upper member 32. In this example, a third sealing member 43 is also provided between the flow path forming member 33 and the ceiling plate member 34 on an outer periphery portion of the flow path forming member 33 so as to be in close contact with the flow path forming member 33 and the ceiling plate member 34. This prevents gas supplied from a gas introduction path 341 described later from leaking between the flow path forming member 33 and the ceiling plate member 34. Further, a fourth sealing member 44 is also provided around the screw 36, thereby securing airtightness with respect to an outer side of a screw hole.

The first to fourth sealing members 41 to 44 are formed by, for example, O-rings, which are elastic annular members and are made of, for example, resin. In FIG. 1 or 4A, the O-rings constituting the sealing members 41 to 43 are depicted between members that are in close contact. However, in reality, as illustrated in FIG. 4B, a groove 45 is formed in one of the members in close contact with each other, and an O-ring 46 is arranged in the groove 45. A space between these members is configured to be airtightly sealed using restoring force of the O-ring 46.

As illustrated in FIGS. 4A and 4B, the film formation gas supply 3 is provided with the gas discharge path 6. The gas discharge path 6 is formed so that an upstream end of the gas discharge path 6 is opened in the gap 38, which is formed by the first sealing member 41, the second sealing member 42, the shower head 31, and the upper member 32, and a downstream end of the gas discharge path 6 is opened in the processing container 2. The gap 38 is a minute gap formed at the joint portion between the shower head 31 and the protrusion 35 of the upper member 32 and may be referred to as the “joint gap 38.”

In this example, as illustrated in FIG. 4B, the gas discharge path 6 is formed in the shower head 31 and includes a downstream discharge path 61 constituting a downstream side of the gas discharge path 6 and an upstream discharge path 62 constituting an upstream side of the gas discharge path 6. In the gas discharge path 6, the side of the joint gap 38 is referred to as the upstream side, and the side to which gas flows by exhaust inside the processing container 2 is referred to as the downstream side.

On the upper surface of the shower head 31, a concave portion 7 which constitutes an upstream side of the gas discharge path 6 together with a connection path forming member 8 described later by being opened in the joint gap 38 is formed. More specifically, the concave portion 7 is provided on the periphery portion of the shower head 31 so as to be directed toward the protrusion 35 of the upper member 32 and is arranged in an outer region of a region facing the wafer W in the shower head 31. As described later, a film is formed in the concave portion 7 by the film formation gas flowing backward through the gas discharge path 6, but the film is formed in the outer region of the region facing the wafer W. Therefore, even if a temperature distribution on a lower surface of the shower head 31 changes slightly, the change in the temperature distribution has no effect or has only a small effect on the in-plane temperature distribution of the wafer W, which is desirable. In addition, the concave portion 7 is locally provided in a circumferential direction of the shower head 31. Therefore, since a location at which the film is formed due to backflowing film formation gas can be suppressed to a small extent, the effect on the in-plane temperature distribution of the wafer W can be suppressed more reliably, which is desirable.

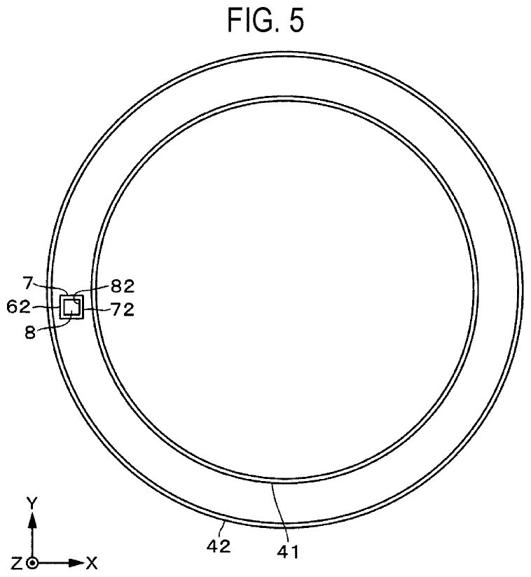

The concave portion 7 of this example is configured as a rectangular shape in a plan view and also a rectangular shape in side view, as illustrated in FIG. 4B and FIG. 5, and has a horizontal bottom surface 71 and a vertical side wall 72. The downstream discharge path 61 is formed so that a downstream end of the downstream discharge path 61 is opened in a vicinity of the opening 241 of the exhaust duct 24 on a lateral side of the shower head 31, extends in the lateral direction (X direction) and then bends upward, and an upstream end of the downstream discharge path 61 is opened in a bottom surface 71 of the concave portion 7.

The connection path forming member 8 made of metal is embedded in the concave portion 7 to block an opening of the downstream discharge path 61. The connection path forming member 8 forms a localized constricted portion in the gas discharge path 6 and forms a connection path for connecting the downstream discharge path 61 and the joint gap 38.

The connection path forming member 8 of this example is formed in a prismatic shape that is slightly smaller than the concave portion 7, as illustrated in FIGS. 4B and 5. As a result, when the connection path forming member 8 is embedded in the concave portion 7, the side walls 82 of the connection path forming member 8 is separated from a side wall 72 of the concave portion 7, and the upstream discharge path 62 is formed between the side walls 72 and 82.

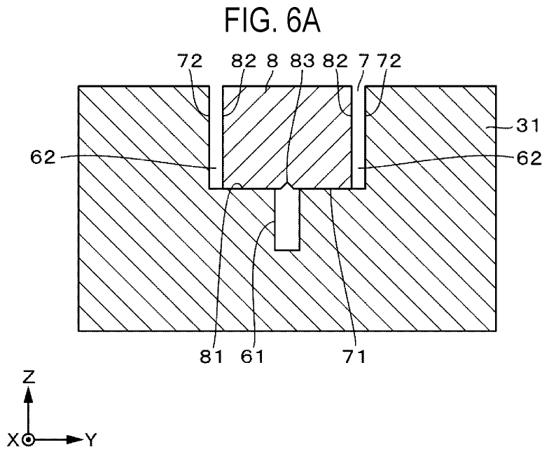

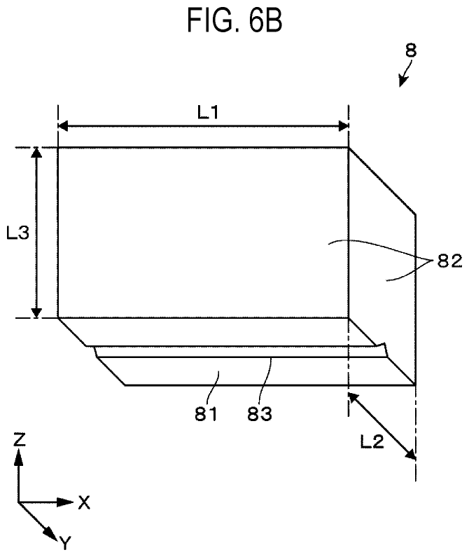

A bottom surface 81 of the connection path forming member 8 constitutes a connecting surface that comes into contact with the bottom surface 71 of the concave portion 7, and a minute groove 83 extending in the lateral direction (X direction) is provided on this bottom surface 81. In this example, as illustrated in FIG. 6A, the groove 83 has a triangular shape in a longitudinal cross-section, and when the connection path forming member 8 is embedded in the concave portion 7, a flow path is formed between the groove 83 and the bottom surface 71 of the concave portion 7. In addition, the longitudinal cross-sectional shape of the groove 83 is desirably triangular because the conductance of the flow path is reduced, thereby more reliably suppressing the inflow of the film formation gas into the joint gap 38 described later. However, this cross-sectional shape is arbitrary and may be, for example, rectangular. The flow path formed by this groove 83 extends horizontally in the lateral direction (X direction), is connected to the downstream discharge path 61 at substantially a center of the length of the groove 83, and both ends of the flow path are connected to the upstream discharge path 62. Accordingly, the flow path formed by the groove 83 functions as a connection path for connecting the joint gap 38 and the downstream discharge path 61 via the upstream discharge path 62.

A cross-sectional area of the flow path formed by the groove 83 is smaller than a cross-sectional area of the upstream discharge path 62 and a cross-sectional area of the downstream discharge path 61 and is formed to be, for example, less than half. Therefore, the flow path formed by the groove 83 is configured as a constricted portion 63 that constricts the gas discharge path 6 in the middle. Since the upstream discharge path 62 is formed by the side wall 82 of the connection path forming member 8 and the side wall 72 of the concave portion 7 and thus has a rectangular frame shape when viewed in a transverse cross section, the cross-sectional area of the upstream discharge path 62 is the area of the rectangular frame. In addition, the diameter of the flow path of the downstream discharge path 61 is, for example, 1 to 3 mm, and the diameter of the flow path of the constricted portion 63 is, for example, 0.1 to 0.5 mm. The cross-section of the flow path of the downstream discharge path 61 is circular, but the cross-section of the flow path of the constricted portion 63 (the cross-section of the groove 83) is triangular or rectangular, not circular, as described above. The diameter of the flow path of the constricted portion 63 mentioned herein is a flow path diameter (the diameter of the flow path) when the cross section of a triangular or rectangular flow path is transformed into a circular flow path having a same area.

In this way, the gas discharge path 6 is configured by connecting the downstream discharge path 61, the constricted portion 63, and the upstream discharge path 62. Therefore, when the gas discharge path 6 is viewed from a downstream end, an upstream end of the downstream discharge path 61 is connected to the constricted portion 63. Further, the flow path is constricted and bent in the lateral direction, and the flow path is bent in the vertical direction to form the upstream discharge path 62 and is connected to the joint gap 38.

In addition, if a length L1 of the connection path forming member 8 in the X direction (the length of the constricted portion 63) is too long, there is a risk that a discharge of the atmospheric air from the gaps 37 and 38 described later may be hindered. If the length L1 is too short, there is a risk that the film formation gas may flow into the gaps 37 and 38 described later. From that viewpoint, the length L1 is desirably, for example, 1 mm to 100 mm. In addition, a length L2 of the connection path forming member 8 in the Y direction is, for example, 100 mm or less, and a length L3 in the Z direction is, for example, 20 mm or less. In addition, the diameter of the flow path or the size of the connection path forming member 8 given as an example herein is a size when the film formation gas supply 3 is placed in an environment of room temperature (15 degrees C. to 30 degrees C.). In addition, although an upper surface of the connection path forming member 8 and the protrusion 35 of the upper member 32 are depicted as being in contact with each other in each drawing, they do not need to be in contact and may be spaced apart.

Referring back to FIG. 1, in the upper member 32, a heater 39 is arranged so as to face the diffusion space 30, for example, between the flow path forming member 33 and the ceiling plate member 34.

In addition, a gas supply path 91 for introducing the film formation gas is connected to the upper member 32, and the gas introduction path 341 is formed in the ceiling plate member 34. The gas flow path 331, an upstream side of which is connected to the gas introduction path 341 and a downstream side of which is branched and connected to the diffusion space 30, is formed in the flow path forming member 33. The film formation gas supplied from a gas supply system 9 to the film formation gas supply 3 via the gas supply path 91 reaches the diffusion space 30 via the gas introduction path 341 and the gas flow path 331 and is discharged from each discharge hole 311 toward the stage 5.

In FIG. 1, the gas supply path 91, an upstream side of which branches into a plurality of paths, and a plurality of gas supply sources 92 are illustrated as the gas supply system 9 in an integrated manner. Regarding the gas supply system 9, the case in which a titanium nitride (TiN) film is formed on the wafer W is described as an example. For example, the film formation apparatus 1 is configured to alternately supply two types of gases as the film formation gas to the processing container 2 and form the TiN film using an atomic layer deposition (ALD) method. As the film formation gas, a raw material gas containing titanium (Ti), for example, titanium tetrachloride (TiCl₄) gas, and a reaction gas containing nitrogen (N), for example, ammonia (NH₃) gas, may be used.

The gas supply source 92 includes a raw gas supply source and a reaction gas supply source and each of the supply sources is connected to the film formation gas supply 3 via the gas supply path 91. The gas supply path 91 is provided with a flow rate controller 93, which includes a valve for supplying and stopping gas or a flow rate regulator for regulating the amount of gas supplied, or a gas storage tank which is not illustrated. The TiCl₄ gas and the NH₃ gas are stored, for example, in the gas storage tank, pressurized to a predetermined pressure, and then supplied into the processing container 2.

In addition, the gas supply source 92 also includes a substitute gas supply source or a cleaning gas supply source, and each of the supply sources is connected to the film formation gas supply 3 via the gas supply path 91. As a substitute gas, an inert gas such as nitrogen (N₂) gas or argon (Ar) gas may be used, and as a cleaning gas, for example, NF₃ gas may be used.

As illustrated in FIG. 1, the film formation apparatus 1 includes a controller 100 that controls the operation of each part constituting the film formation apparatus 1. The controller 100 is composed of, for example, a computer having a central processing unit (CPU) and a storage, which are not illustrated, and the storage stores a program in which a group of steps (commands) related to control necessary for forming the TiN film described later is organized. The program is stored in a storage medium such as a hard disk, a compact disc, a magneto-optical disc, a memory card, or a nonvolatile memory and is installed in the computer therefrom.

### Formation of TiN Film in Film Formation Apparatus

Next, a method of performing a film formation process of the TiN film using the film formation apparatus 1 having the configuration described above will be described as an example of the case in which the film formation process is resumed after maintenance of the film formation apparatus 1 is completed.

As described earlier, maintenance includes a process of disassembling and assembling the film formation gas supply 3 in an atmospheric environment. By this maintenance, the film formation gas supply 3 is in a state in which the atmospheric air is present in the gap 37, the joint gap 38 which is formed by the first sealing member 41, the second sealing member 42, the shower head 31, and the upper member 32, or the gas discharge path 6.

Before performing the film formation process, the interior of the processing container 2 is depressurized to a vacuum atmosphere to remove any remaining foreign substances such as water. In parallel with this depressurization, the heater 39 of the film formation gas supply 3 is heated to a predetermined set temperature, for example, 170 degrees C., and the heater 51 of the stage 5 is heated to a predetermined set temperature, for example, 400 degrees C. so that the wafer W may be received and processed in the processing container 2.

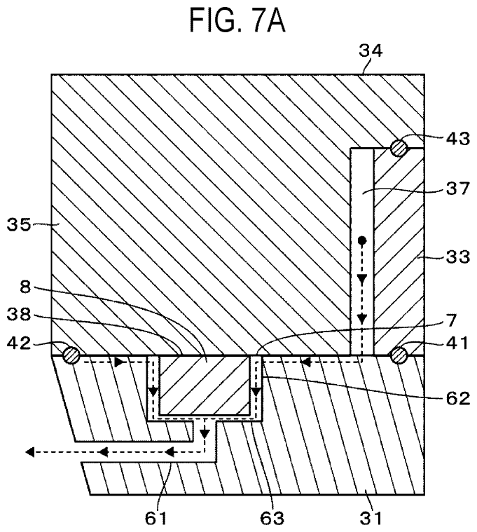

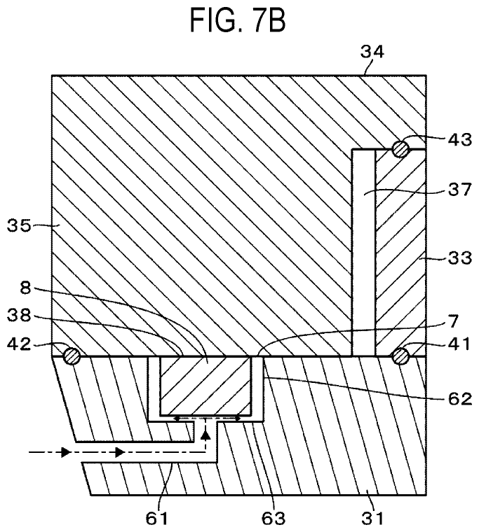

As the temperature of the film formation gas supply 3 increases due to thermal conduction from the heater 39 and radiant heat from the heater 51, caused by the temperature increase of the heaters 39 and 51, the atmospheric air temperature of the gaps 37 and 38 also increases, thereby increasing the diffusivity of the atmospheric air. Since the inside of the processing container 2 is exhausted, the atmospheric air with such increased diffusivity flows to the outside of the shower head 31 by passing through the constricted portion 63 of the gas discharge path 6 and is exhausted toward the exhaust duct 24, as indicated by a broken line in FIG. 7A showing the flow of the atmospheric air.

In a state in which the heater 39 of the film formation gas supply 3 and the heater 51 of the stage 5 reach the set temperatures, respectively, a pressure inside the processing container 2 becomes a predetermined vacuum pressure, and the stage 5 is lowered to a delivery position so that the wafer W is stored in the processing container 2 through cooperative operation of an external transfer mechanism (not illustrated) and the support pins 27. Then, the wafer W is placed on the stage 5 heated to a film formation temperature (set temperature) by the heater 51, and the stage 5 is moved to a processing position.

Next, a process of forming a film is performed by supplying the film formation gas from the film formation gas supply 3 to the surface of the wafer W heated to the film formation temperature. In this process, the film formation gas (TiCl₄ gas and NH₃ gas), and the substitute gas (N₂ gas) for substituting an internal atmosphere of the processing container 2 are repeatedly supplied in the order of TiCl₄ gas→N₂ gas→NH₃ gas→N₂ gas. In this case, the supply time of the TiCl₄ gas or the NH₃ gas, which is the film formation gas, is 5 seconds or less, for example.

As a result, the two types of film formation gases adsorbed onto the wafer W react with each other to form a molecular layer of TiN, and this molecular layer is deposited to form the titanium nitride (TiN) film.

In this way, a supply cycle of the film formation gas and the substitute gas described above is repeated several tens to several hundreds of times to form the TiN film having a target film thickness. Thereafter, the supply of gas is stopped, the stage 5 is lowered to the delivery position, and the gate valve 23 is opened to take out the wafer W.

During the film forming process, since the downstream end of the downstream discharge path 61 is opened inside the processing container 2, there are cases in which the film formation gas flows back into and enters the downstream discharge path 61. However, the upstream end of the downstream discharge path 61 is connected to the constricted portion 63. At a connection portion between the downstream discharge path 61 and the constricted portion (connection path) 63, a flow direction of the downstream discharge path 61 and a flow direction of the constricted portion 63 differ from each other, so this connection portion forms a curved flow path. In this way, in the gas discharge path 6, since a flow path narrows at the constricted portion 63 and a gas flow direction changes at the constricted portion 63, it is difficult for the film formation gas to flow in the constricted portion 63.

For this reason, as indicated by a dash-dotted line in FIG. 7B showing the flow of the film formation gas, the flow of the film formation gas to an upstream side is suppressed by the constricted portion 63 formed by the connection path forming member 8, so that the film formation gas has difficulty reaching the upstream discharge path 62, and the intrusion of the film formation gas into the upstream discharge path 62 is suppressed.

In particular, in the ALD method, since the supply time of TiCl₄ gas or NH₃ gas, which is the film formation gas, is extremely short, the film formation gas remains in the constricted portion 63, thereby further preventing permeation of the film formation gas upstream beyond the constricted portion 63.

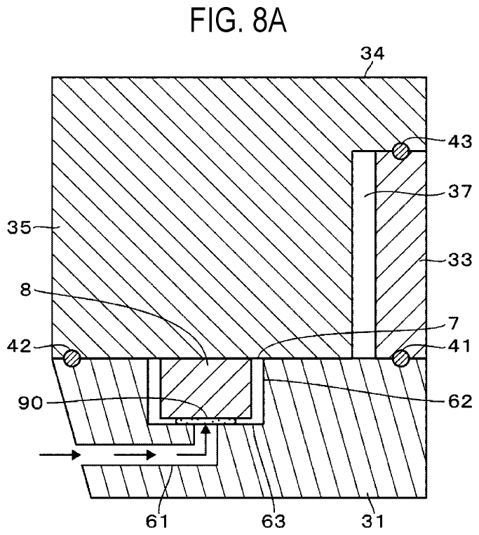

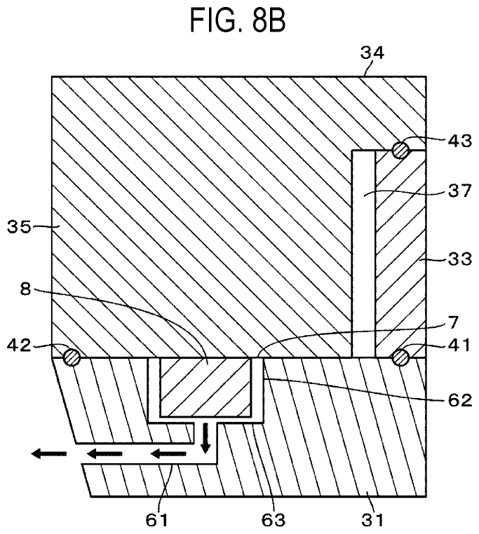

In this way, while the film formation gas stays in the constricted portion 63 and, as illustrated in FIG. 8A, a film 90 is deposited in the constricted portion 63, film formation is limited to that area. Since the flow path remains constricted at the constricted portion 63 due to the film formation, permeation of the film formation gas upstream beyond the constricted portion 63 is further suppressed. Therefore, the film formation gas does not reach the joint portion between the shower head 31 and the upper member 32, and film formation in the joint portion can be suppressed.

In this way, in the film formation apparatus 1, after the film formation process of the TiN film is performed on a plurality of wafers W, a cleaning process is performed. This cleaning process is performed, for example, by vacuum-exhausting the inside of the processing container 2 using the exhaust mechanism 26 via the exhaust duct 24, heating the inside of the processing container 2 using the heaters 39 and 51, and supplying NF₃ gas, which is the cleaning gas, from the gas supply system 9, as indicated by a solid line in FIG. 8A.

The cleaning gas is supplied into the processing container 2 via the film formation gas supply 3 and comes into contact with an attached film inside the processing container 2, thereby peeling the film from the processing container 2. The cleaning gas including the peeled film is discharged to the outside via the exhaust duct 24 along with exhaust by the exhaust mechanism 26.

In this case, as illustrated in FIG. 8A, the cleaning gas also enters the gas discharge path 6 of the film formation gas supply 3 and comes into contact with the film 90 attached to the constricted portion 63. As a result, the film 90 is peeled from the constricted portion 63, and as indicated by a thick line in FIG. 8B, the cleaning gas including the peeled film 90 is discharged via the gas discharge path 6 and removed.

According to the above-described embodiment, since the gas discharge path 6 is provided in the film formation gas supply 3, the gaps 37 and 38 formed by the first sealing member 41, the second sealing member 42, the shower head 31, and the upper member 32 can be exhausted through the gas discharge path 6.

As a result, as already described, even if the atmospheric air remains in the film formation gas supply 3, the atmospheric air can be exhausted before the film forming process, and the reaction between the atmospheric air and the film formation gas can be suppressed during the film forming process. In other words, since a vacuum formation time required to exhaust the atmospheric air before starting the film forming process is shortened, the processing efficiency of the apparatus can be increased.

In addition, by providing the localized constricted portion 63 in the gas discharge path 6, permeation of the film formation gas into the joint portion between the shower head 31 and the upper member 32 is suppressed, thereby preventing film formation in the joint portion. As a result, occurrence of scratches in the joint portion, which has been an issue due to film formation in the joint portion, can be suppressed, a risk of occurrence of the particles is reduced, thermal conduction in the joint portion is improved, and the temperature variations of the shower head 31 for each processed wafer W (furthermore, processing temperature variations between the wafers W) can be suppressed.

In addition, as described with reference to FIG. 8A, in the film formation gas supply 3, the film formation process is performed in the constricted portion 63, i.e., in the joint portion between the shower head 31 and the connection path forming member 8. However, as compared to the film formation gas supply 3A described with reference to FIG. 2, an area in which the film is formed is suppressed to be small. For this reason, the risk of occurrence of particles or temperature variations of the shower head 31, as described above, is suppressed.

Further, in the film formation gas supply 3A, if the deterioration of the upper member 32 caused by film formation in the joint portion between the shower head 31 and the upper member 32 is significant, the upper member 32 is replaced. However, since the upper member 32 constitutes the ceiling plate of the processing container 2, the upper member 32 is relatively large. Therefore, the labor and cost of replacement of the upper member 32 increase. In contrast, even if the film formation causes significant degradation of the connection path forming member 8 in the joint portion between the shower head 31 and the connection path forming member 8 in the film formation gas supply 3, it is sufficient to replace the connection path forming member 8, which is a relatively small member, resulting in low cost and simple operation. In other words, the configuration of the film formation gas supply 3 is advantageous in terms of maintenance of the apparatus.

In the above-described example, since the constricted portion 63 is formed by embedding the connection path forming member 8 in which the groove 83 is formed within the concave portion 7, the constricted portion 63 can be formed by a simple method.

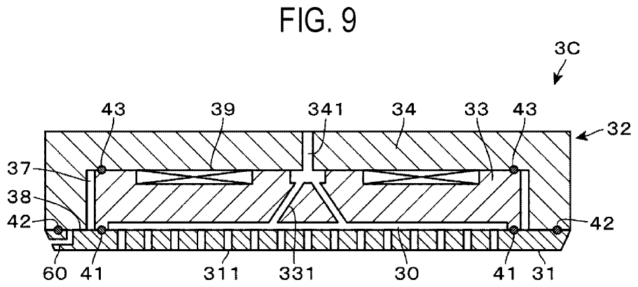

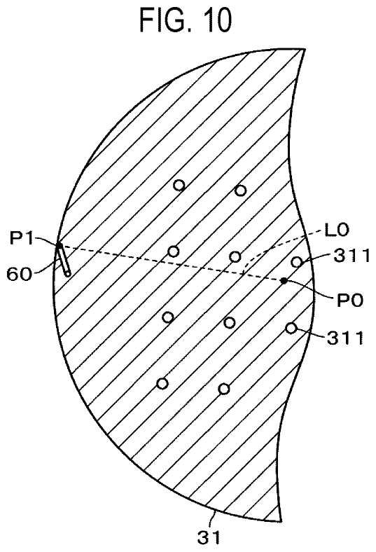

In the above, the film formation apparatus of the present disclosure may be configured such that only the gas discharge path 60 is provided in the film formation gas supply 3C, as illustrated in FIG. 9. The gas discharge path 60 is formed so that the upstream end of the gas discharge path 60 is opened in the gap 38, which is formed by the first sealing member 41, the second sealing member 42, the shower head 31, and the upper member 32, and the downstream end of the gas discharge path 60 is opened in the processing container 2. The gas discharge path 60 of this example is formed with a flow path diameter of, for example, 1 to 5 mm. The other configurations of the film formation gas supply 3C are the same as those of the film formation gas supply 3.

In this configuration, although the constricted portion 63 is not provided in the gas discharge path 60, the gap 38 can be exhausted via the gas discharge path 60. Therefore, the atmospheric air that enters the film formation gas supply 3C during manufacture or maintenance of the apparatus can be exhausted and removed via the gas discharge path 60.

However, since the constricted portion 63 is not provided, there is a risk that the film formation gas may flow into the gaps 37 and 38. In terms of more reliably suppressing such inflow, the configuration of the film formation gas supply 3 described with reference to FIG. 4B is more desirable.

FIG. 10 is a transverse cross-sectional plan view of the shower head 31. Regarding the gas discharge path 60, it is desirable to form the gas discharge path 60 relatively long in order to suppress the inflow of the film formation gas into the gaps 37 and 38. In order to avoid forming the gas discharge path 60 in a region in which the discharge holes 311 of the shower head 31 are formed (the region facing the wafer W), for example, as illustrated in this drawing, the gas discharge path 60 is formed to extend in a direction inclined relative to a straight line L0 connecting a point P1, which is the downstream end of the gas discharge path 60 when seen in a plan view, and a center PO of the shower head 31. In addition, the downstream discharge path 61 of the film formation gas supply 3 can also be formed to extend in the direction inclined relative to the straight line L0, similarly to the gas discharge path 60 illustrated in FIG. 10.

In the above, in the film formation gas supply 3 of a first embodiment, when forming the constricted portion 63 by combining the concave portion 7 and the connection path forming member 8, a minute groove may be formed on the bottom surface 71 of the concave portion 7 instead of the bottom surface 81 of the connection path forming member 8.

In addition, a positional relationship between the concave portion 7, the gas discharge path 6, and the connection path forming member 8 is not limited to the above-described example. For example, a configuration may be possible in which the upstream end of the downstream discharge path 61 of the gas discharge path 6 is opened in the side wall of the concave portion 7. In this case, the connection path forming member 8 is embedded in the concave portion 7 so as to block the opening of the downstream discharge path by contacting the side wall of the concave portion 7, and the minute groove is formed in the vertical direction on a surface of the connection path forming member 8 that contacts the side wall of the concave portion 7. In this example, the constricted portion 63 is extended in the vertical direction, and one end of the constricted portion 63 is opened in a gap of the joint portion, so that one end of the constricted portion 63 forms the upstream end of the gas discharge path 6. In addition, the constricted portion may be provided by forming a groove in the side wall of the concave portion 7 instead of the connection path forming member 8.

In addition, the gas discharge path 6 may be provided in the upper member 32 instead of being provided in the shower head 31. In this case, the concave portion 7 is provided to be opened in a gap between the shower head 31 and the upper member 32 on a lower surface of the upper member 32. The constricted portion 63 is configured so that the upstream end of the downstream discharge path 61 is opened in the concave portion 7, the connection path forming member 8 is embedded to block this opening, and a minute groove is formed on one side of the connection path forming member 8 and the concave portion 7.

The shape of the concave portion 7 or the connection path forming member 8, provided on one side of the shower head 31 and the upper member 32, is not limited to the above-described configuration. In addition, the constricted portion 63 provided in the gas discharge path 6 may be formed by locally narrowing a flow path itself constituting the gas discharge path 6. That is, as illustrated in FIG. 9, the gas discharge path 60 may be formed, and a flow path diameter of a part of the gas discharge path 60 may be formed to be smaller than a flow path diameter of another part of the gas discharge path 60.

In addition, the film formation process of the present disclosure is applicable to a film formation process in which the wafer is stored in the processing container set to a vacuum atmosphere, and a film formation gas is supplied to the wafer from the film formation gas supply, thereby forming a film. Therefore, the film forming process is not limited to ALD and may also be chemical vapor deposition (CVD). Further, when the film formation process is applied to ALD, the discharge of the film formation gas becomes intermittent, and the time for one discharge is relatively short as described as an example. Therefore, the inflow of the film formation gas from the constricted portion 63 to the gaps 37 and 38 is more reliably suppressed.

It should be noted that the embodiments disclosed herein are exemplary in all aspects and are not restrictive. The above-described embodiments may be omitted, replaced, modified, or combined in various forms without departing from the scope and spirit of the appended claims.

### Evaluation Tests

Evaluation tests performed in relation to the technology of the present disclosure are described. These evaluation tests were performed by performing a film formation process of a TiN film on a plurality of wafers using the film formation apparatus 1 illustrated in FIG. 1, performing cleaning, disassembling the film formation gas supply 3, and visually checking the states of the shower head 31 and the upper member 32.

The film formation process was started after performing maintenance of the film formation apparatus 1 and then performing a process of exhausting atmospheric air remaining in the film formation gas supply 3 for six hours. The process of exhausting the atmospheric air, the film formation process of the TiN film, and the cleaning process, after the maintenance, were performed as described above.

In addition, the evaluation tests were similarly conducted for the cases in which the film formation gas supply 3 (Embodiment 1) was replaced with the film formation gas supply 3C (Embodiment 2) illustrated in FIG. 9, the film formation gas supply 3A (Comparative Example 1) of the conventional configuration illustrated in FIG. 2, and the film formation gas supply 3B (Comparative Example 2) of the conventional configuration illustrated in FIG. 3. In the film formation gas supply 3C of Embodiment 2, the gas discharge path 60 was formed so that a flow path diameter was 1 mm and the length of a flow path from the downstream end to a portion bent upward (i.e., the length of a portion extending in the lateral direction) was 70 mm. In addition, the film formation gas supply 3 of Embodiment 1 was configured so that the concave portion 7 and the connection path forming member 8 were provided at the joint portion between the shower head 31 and the upper member 32 in the gas discharge path 60 of the film formation gas supply 3C, and a flow path diameter of the constricted portion 63 was 0.1 mm. Even in Embodiment 1, the length of the flow path from the downstream end of the gas discharge path 60 to the portion bent upward was 70 mm, which is the same as in Embodiment 2.

Results of these tests will now be described.

In the film formation gas supply 3A of Comparative Example 1, it was confirmed that a residue remained in the entire area forming the joint portion with the upper member 32 on a back surface (upper surface) of the shower head 31 and that the joint portion deteriorated due to occurrence of scratches compared to before the film forming process was performed. In this film formation gas supply 3A, it is thought that the film formation gas flowed back into the joint portion and formed a film over the entire joint portion in the shower head 31. It is estimated that a film forming residue remained attached even after cleaning was performed, because the gas has difficulty flowing back to the joint portion.

In the film formation gas supply 3B of Comparative Example 2, since no residue was visible on the back surface of the shower head 31, it was confirmed that the film formation gas was prevented from flowing back into the joint portion between the shower head 31 and the upper member 32 by providing the second sealing member 42.

However, a black film was observed to be attached at a position at which the first to third sealing members 41 to 43 were provided around the screw 36. This is presumed to be because the atmospheric air remaining in the film formation gas supply 3B reacts with the first to third sealing members 41 to 43 and modifies the first to third sealing members 41 to 43.

Subsequently, in the film formation gas supply 3C of Embodiment 2, no film forming residue was visible on the back surface of the shower head 31, but a small amount of residue was confirmed near the upstream end of the gas discharge path 60 that is opened in the gap 38.

It is presumed that this residue, which is visibly different from the black film of Comparative Example 2, was formed by the film formation gas entering the gas discharge path 60. However, since the amount of the confirmed residue was small, it was recognized that even with the configuration of Embodiment 2, there is an effect in that the atmospheric air remaining in the film formation gas supply 3C is discharged in comparison to the conventional configurations, thereby suppressing film formation in the joint portion between the shower head 31 and the upper member 32.

In the film formation gas supply 3 of Embodiment 1, the film forming residue was not visually confirmed on the back surface of the shower head 31, and no deterioration, such as scratches, was observed at the joint portion between the shower head 31 and the upper member 32 compared to before the film forming process was performed. Accordingly, in the film formation gas supply 3 of Embodiment 1, it was confirmed that the residual atmospheric air was exhausted, the reaction between the atmospheric air and the film formation gas was suppressed, and a backflow of the film formation gas was suppressed.

According to the present disclosure in some embodiments, it is possible to suppress occurrence of a problem due to gas accumulation in a gap formed in the film formation gas supply including the shower head.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A film formation apparatus, comprising:
a processing container configured to store a substrate, an interior of the processing container being under a vacuum atmosphere;
a film formation gas supply including:
a shower head provided with a plurality of discharge holes configured to supply a film formation gas for forming a film on the substrate; and
an upper member configured to form a diffusion space of the film formation gas communicating with the plurality of discharge holes and provided above the shower head inside the processing container;
an annular first sealing member surrounding the diffusion space in a plan view and in close contact with the shower head and the upper member;
an annular second sealing member surrounding the first sealing member in the plan view and in close contact with the shower head and the upper member; and
a gas discharge path formed in the film formation gas supply,
wherein an upstream end of the gas discharge path is opened in a gap formed by the first sealing member, the second sealing member, the shower head, and the upper member, and
wherein a downstream end of the gas discharge path is opened in the processing container.

2. The film formation apparatus of claim 1, wherein the gas discharge path includes a localized constricted portion.

3. The film formation apparatus of claim 2, wherein a concave portion that is opened in the gap is provided in one of an upper surface of the shower head and a lower surface of the upper member,
wherein an upstream end of a downstream discharge path forming a downstream side of the gas discharge path is opened in the concave portion,
wherein the film formation apparatus further comprises a connection path forming member embedded in the concave portion to block an opening of the upstream end of the downstream discharge path and forming a connection path for connecting the downstream discharge path and the gap, and
wherein the connection path is the constricted portion.

4. The film formation apparatus of claim 3, wherein the upstream end of the downstream discharge path is opened in a bottom surface of the concave portion,
wherein the connection path forming member is spaced apart from a side wall of the concave portion to form an upstream discharge path serving as an upstream side of the gas discharge path between the side wall and the connection path forming member, and
wherein the connection path forming member has a connection surface that contacts the bottom surface of the concave portion and has a groove formed on the connection surface to connect the downstream discharge path and the upstream discharge path to form the connection path.

5. The film formation apparatus of claim 3, wherein the concave portion and the gas discharge path are provided in the shower head.

6. A film formation method, comprising:
storing a substrate in a processing container, an interior of the processing container being under a vacuum atmosphere;
forming a film on the substrate by supplying a film formation gas by a film formation gas supply; and
exhausting a gap via a gas discharge path,
wherein the film formation gas supply includes:
a shower head provided with a plurality of discharge holes; and
an upper member configured to form a diffusion space of the film formation gas communicating with the plurality of discharge holes and provided above the shower head inside the processing container;
wherein the gas discharge path is formed in the film formation gas supply,
wherein the gap is formed by an annular first sealing member surrounding the diffusion space in a plan view and in close contact with the shower head and the upper member, an annular second sealing member surrounding the first sealing member in the plan view and in close contact with the shower head and the upper member, the shower head, and the upper member,
wherein an upstream end of the gas discharge path is opened in the gap, and
wherein a downstream end of the gas discharge path is opened in the processing container.
